(19) United States
(12) Patent Application Publication
(10) Pub. No.: US 2020/0227374 A1
(43) Pub. Date: Jul. 16, 2020

(54) FOWBCSP CHIP MODULE WITH PACKAGING STRUCTURE AND MANUFACTURING METHOD OF THE SAME

(71) Applicant: Shih-Chi CHEN, Taipei City (TW)

(72) Inventor: Shih-Chi CHEN, Taipei City (TW)

(21) Appl. No.: 16/246,567

(22) Filed: Jan. 14, 2019

(51) Int. Cl. H01L 23/00; H01L 27/146; H01L 23/31; H01L 23/498; H01L 23/538; H01L 21/56; H01L 21/48; H05K 1/18; H05K 1/11

(52) U.S. Cl. CPC H01L 24/48; H05K 2201/10734; H01L 27/14618; H01L 27/14636; H01L 23/3114; H01L 23/49816; H01L 23/5386; H01L 21/568; H01L 24/85; H01L 21/4853; H01L 27/14683; H05K 1/181; H05K 1/11; H01L 2224/48228; H01L 2224/4824; H01L 2224/8592; H05K 2201/10378; H01L 27/14643

(57) ABSTRACT

A FOWBCSP chip module with a packaging structure has the following steps of: a chip having joints on an upper side thereof; a first packing structure enclosing a lower side and lateral sides of the chip; a substrate at the upper side of the chip; the substrate being formed with a plurality of penetrating through holes; and an upper side of the substrate being formed with a plurality of joints; and conductive wires passing through the through holes of the substrate to connect the joints of the substrate and the joints of the chip. Each of the through holes of the substrate is formed with a respective second packaging structure by filling gluing material to seal the through hole of the substrate and each of the joints on the upper side of the substrate is formed with a conductive ball, respectively. A method for forming the module is also included.

### FIELD OF THE INVENTION

The present invention is related to semiconductor packaging, and in particular to a FOWBCSP (Fan out wafer bonding chip scale package) chip module with a packaging structure and manufacturing method of the same.

### BACKGROUND OF THE INVENTION

In the prior art semiconductor packaging structure, a chip has a plurality of joints on an upper side of the chip and a substrate has a plurality of joints on an upper side of the substrate. The joints of the chip are connected to the joints of the substrate by using a plurality of conductive wires. The substrate has through holes which are sealed by conductive material so that the joints of the substrate are guided to a bottom side of the substrate. A circuit board is placed on the bottom side of the substrate. The circuit board has a plurality of joints to be connected to the joints guided to the bottom side of the substrate so as to form an electrical connection therebetween.

During a process of packaging, it is necessary to form a large packaging structure to enclose the chip and the substrate so as to avoid the conductive wires to expose out. As a result, higher cost is needed and time for manufacturing is prolonged.

Moreover, the substrate must have a large number of through holes which are filled fully by conductive material. Each of the through holes should not be connected to each other for avoiding short-circuit. Therefore, the process of packaging is time-consuming and work-consuming. Moreover, above process also increase the whole cost in manufacturing.

To resolve the above disadvantages in the prior art, the present invention introduces a brand new FOWBCSP chip module with a packaging structure and manufacturing method of the same.

### SUMMARY OF THE INVENTION

Accordingly, to overcome the defects in the prior art, the present invention provides a FOWBCSP (Fan out wafer bonding chip scale package) chip module with a packaging structure and manufacturing method of the same, wherein only a few of through holes are formed on the substrate, so that a plurality of conductive wires can pass through of the through holes in the same time. As a result, the substrate does not need to have a large number of through holes as those used prior art, so that the time and cost of the process are reduced. Moreover, in the present invention, only a few of areas with exposed conductive wires need to be packaged. The packaging area does not need to cover the whole upper side of the chip and the substrate as that of the prior art. Therefore, the packaging process in the present invention saves the cost and time in manufacturing. In the present invention, the conductive wires have short length, and most parts of the conductive wires are hidden within the through holes. As a result, the conductive wires do not expose obviously and many dangerous issues are avoided.

To achieve above mentioned objects, the present invention provides a FOWBCSP chip module with a packaging structure, comprising: a chip having joints on an upper side thereof; a first packing structure enclosing a lower side and lateral sides of the chip; a substrate at the upper side of the chip; the substrate being formed with a plurality of penetrating through holes at positions corresponding to the joints of the chip; and an upper side of the substrate being formed with a plurality of joints; and conductive wires passing through the through holes of the substrate to connect the joints of the substrate and the joints of the chip; and wherein each of the through holes of the substrate is formed with a respective second packaging structure by filling gluing material to seal the through hole of the substrate and each of the joints on the upper side of the substrate is formed with a conductive ball, respectively.

The present invention further provides a manufacturing method for a FOWBCSP chip module with a packaging structure, comprising the following steps of: Step A: taking a chip; a lower side of the chip having a plurality of joints; taking a non-adhesive film to be on the lower side of the chip; then taking a supporting plate to be under the non-adhesive film; forming a first packaging structure to enclose an upper side and lateral sides of the chip so as to form a first structure; and then transferring the first structure to a predetermined position; Step B: removing the supporting plate and the non-adhesive film and then turning the chip to be upside down, so that the joints of the chip are at an upper side of the chip; and the first packaging structure is at a lower side of the chip; Step C: moving a substrate to be on the upper side of the chip; wherein the substrate has a plurality of penetrating through holes corresponding to locations of the joints of the chip; and an upper side of the substrate is formed with a plurality of joints; taking a plurality of conductive wires to pass through the through holes of the substrate to connect the joints of the substrate and the joints of the chip; and Step D: taking gluing material to seal the through holes of the substrate to form a second packaging structure; and forming a plurality of conductive balls to be on the joints of the substrate to form an integrated structure.

### BRIEF DESCRIPTION OF THE DRAWINGS

FIG. 1 is an exploded schematic view about the chip, substrate and circuit board in the first embodiment.

FIG. 2A is a schematic cross sectional view showing the arrangement of the elements in the step A of the first embodiment.

FIG. 2B is a schematic cross sectional view showing the arrangement of the elements in the step B of the first embodiment.

FIG. 2C is another schematic cross sectional view showing the arrangement of the elements in the step B of the first embodiment.

FIG. 2D is a schematic cross sectional view showing the arrangement of the elements in the step C of the first embodiment.

FIG. 2E is a schematic cross sectional view showing the arrangement of the elements in the step D of the first embodiment.

FIG. 2F is a schematic view showing an application of the first embodiment.

FIG. 3A is a schematic cross sectional view showing the arrangement of the elements in the first embodiment.

FIG. 3B is a schematic cross sectional view showing an application of the arrangement of the elements in FIG. 3A.

FIG. 4A is a schematic cross sectional view showing the arrangement of the elements in the step A of the second embodiment.

FIG. 4B is a schematic cross sectional view showing the arrangement of the elements in the step B of the second embodiment.

FIG. 4C is another schematic cross sectional view showing the arrangement of the elements in the step B of the second embodiment.

FIG. 4D is a schematic cross sectional view showing the arrangement of the elements in the step C of the second embodiment.

FIG. 4E is a schematic cross sectional view showing the arrangement of the elements in the step D of the second embodiment.

FIG. 5 is a schematic cross sectional view showing the arrangement of the elements in the second embodiment.

FIG. 6 is an exploded schematic view about the plural chips, substrate and circuit board in the third embodiment.

FIG. 7A is a schematic cross sectional view showing the arrangement of the elements in the step A1 of the third embodiment.

FIG. 7B is a schematic cross sectional view showing the arrangement of the elements in the step B1 of the third embodiment.

FIG. 7C is another schematic cross sectional view showing the arrangement of the elements in the step B1 of the third embodiment.

FIG. 7D is a schematic cross sectional view showing the arrangement of the elements in the step C1 of the third embodiment.

FIG. 7E is a schematic cross sectional view showing the arrangement of the elements in the step D1 of the third embodiment.

FIG. 7F is a schematic view showing an application of the third embodiment.

FIG. 8 is a schematic cross sectional view showing the arrangement of the elements in the third embodiment.

FIG. 9A is a schematic cross sectional view showing the arrangement of the elements in the step A2 of the fourth embodiment.

FIG. 9B is a schematic cross sectional view showing the arrangement of the elements in the step B2 of the fourth embodiment.

FIG. 9C is another schematic cross sectional view showing the arrangement of the elements in the step B2 of the fourth embodiment.

FIG. 9D is a schematic cross sectional view showing the arrangement of the elements in the step C2 of the fourth embodiment.

FIG. 9E is another schematic cross sectional view showing the arrangement of the elements in the step C2 of the fourth embodiment.

FIG. 9F is a schematic cross sectional view showing the arrangement of the elements in the step D2 of the fourth embodiment.

FIG. 9G is an application of the fourth embodiment.

FIG. 10A is a schematic cross sectional view showing the arrangement of elements in the fourth embodiment.

FIG. 10B is a schematic cross sectional view showing an application of the arrangement of the elements in FIG. 10A.

FIG. 11 is a flow diagram showing the steps in the process of the first embodiment.

FIG. 12 is a flow diagram showing the steps in the process of the second embodiment.

FIG. 13 is a flow diagram showing the steps in the process of the third embodiment.

FIG. 14 is a flow diagram showing the steps in the process of the fourth embodiment.

### DETAILED DESCRIPTION OF THE INVENTION

In order that those skilled in the art can further understand the present invention, a description will be provided in the following in details.

However, these descriptions and the appended drawings are only used to cause those skilled in the art to understand the objects, features, and characteristics of the present invention, but not to be used to confine the scope and spirit of the present invention defined in the appended claims.

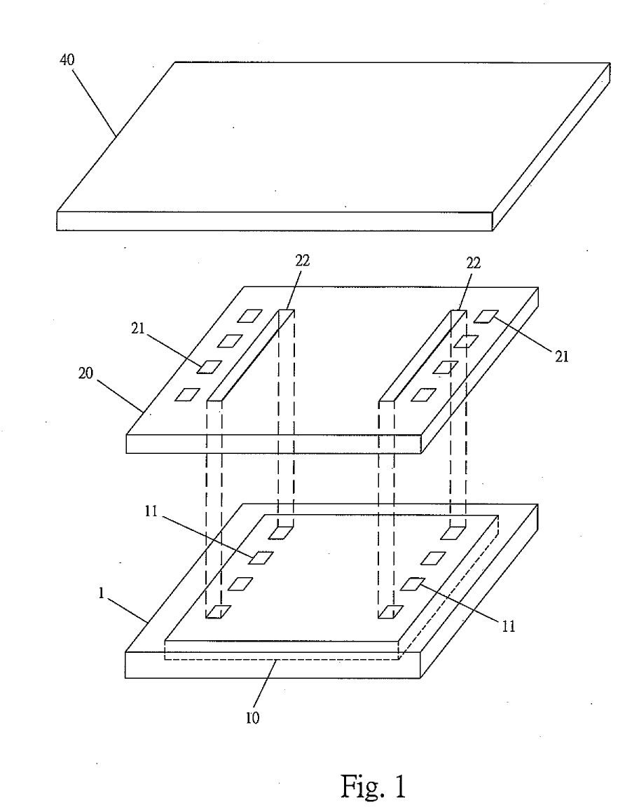

With reference to FIGS. 1 to 2F, and 11, the first embodiment of the present invention is illustrated. The first embodiment in the present invention includes the following steps of:

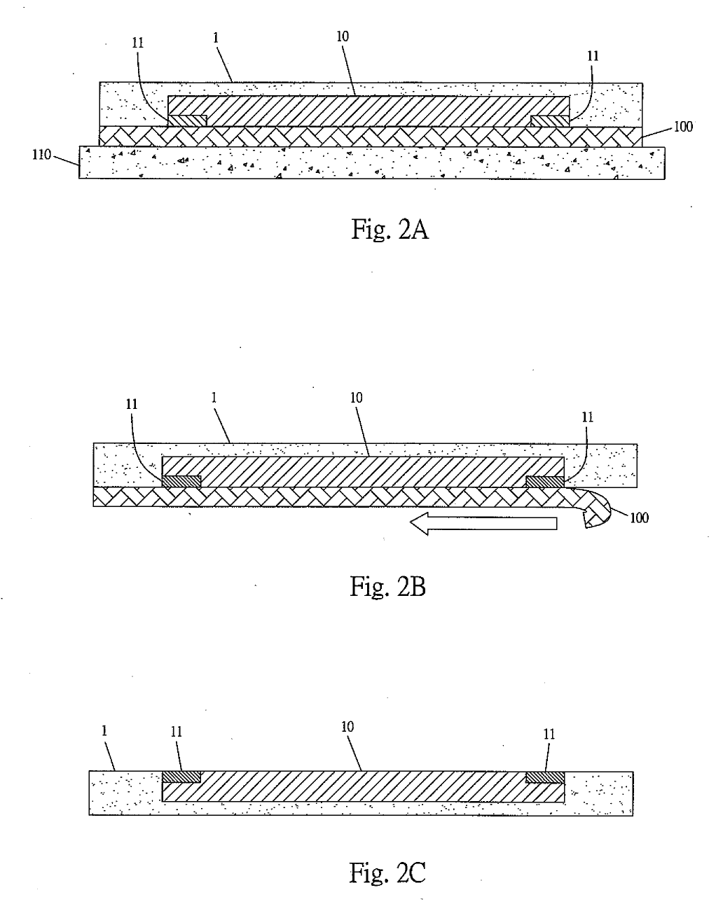

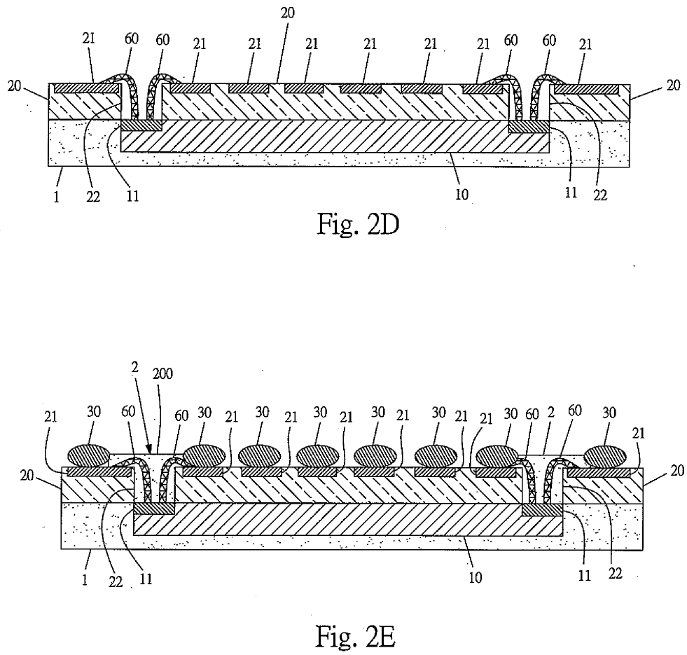

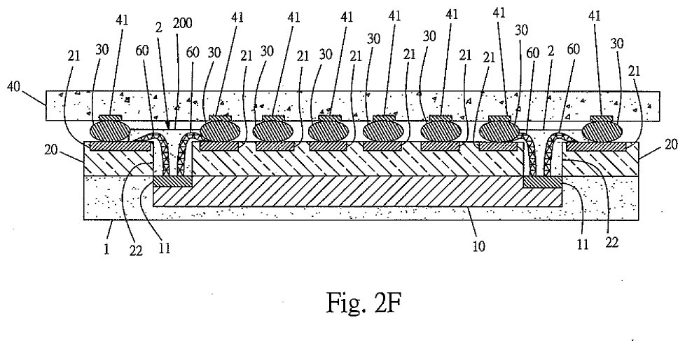

Step A: as shown in FIG. 2A, taking a chip 10; a lower side of the chip 10 having a plurality of joints 11; taking a non-adhesive film 100 to be on the lower side of the chip 100; then taking a supporting plate 110 to be under the non-adhesive film 100; forming a first packaging structure 1 to enclose an upper side and lateral sides of the chip 10 so as to form a first structure; and then transferring the first structure to a predetermined position.

Step B: with reference to FIG. 2B, removing the supporting plate 110 and the non-adhesive film 100 and then turning the chip 10 to be upside down, as shown in FIG. 2C so that the joints 11 of the chip 10 are at an upper side of the chip 10; and the first packaging structure 1 is at a lower side of the chip 10.

Step C: referring to FIG. 2D, moving a substrate 20 to be on the upper side of the chip 10; wherein the substrate 20 has a plurality of penetrating through holes 22 corresponding to locations of the joints 11 of the chip 10; and an upper side of the substrate 20 is formed with a plurality of joints 21; taking a plurality of conductive wires 60 to pass through the through holes 22 of the substrate 20 to connect the joints 21 of the substrate 20 and the joints 11 of the chip 10.

Step D: as shown in FIG. 2E, taking gluing material 200 to seal the through holes 22 of the substrate 20 to form a second packaging structure 2; and forming a plurality of conductive balls 30 (tin balls or solder balls) to be on the joints 21 of the substrate 20 to form an integrated structure.

As shown in FIG. 2F, in application, a circuit board 40 is arranged on the upper side of the substrate 20 of the integrated structure, wherein the circuit board 40 has a plurality of joints 41 to connect the conductive balls 30 on the joints 21 of the substrate 20 so as to form an electrical connection therebetween.

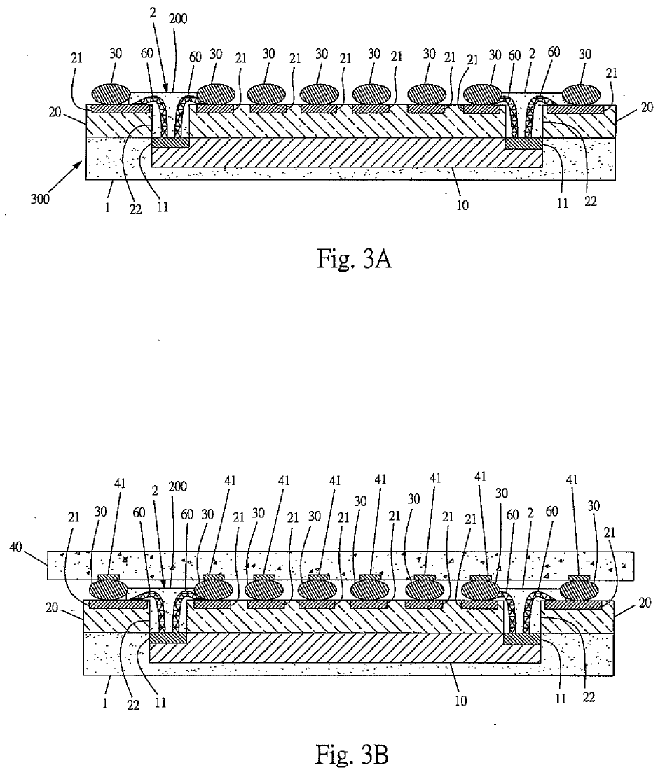

With reference to FIG. 3A, above mentioned structure can be formed as a FOWBCSP (Fan out wafer bonding chip scale package) chip module with a packaging structure 300. The structure contains the following elements.

A chip 10 has an upper side; and the upper side thereof has a plurality of joints 11.

A first packaging structure 1 is formed on a lower side and lateral sides of the chip 10.

A substrate 20 is installed on the upper side of the chip 10. The substrate 20 has a plurality of penetrating through holes 22 which are located corresponding to locations of the joints 11 of the chips 10; and an upper side of the substrate 20 is formed with a plurality of joints 21. A plurality of conductive wires 60 pass through the through holes 22 of the substrate 20 to be connected to the joints 21 of the substrate 20 and the joints 11 of the chip 10.

Each of the through holes 22 of the substrate 20 is sealed by gluing material 200 to form a second packaging structure 2. The joints 21 on the upper side of the substrate 20 have a plurality of conductive balls 30 (tin balls or solder balls).

With reference to FIG. 3B, in application, a circuit board 40 is arranged on the upper side of the substrate 20. The circuit board 40 has a plurality of joints 41 to be connected to the conductive balls 30 on the joints 21 of the substrate 20 so as to form an electrical connection therebetween.

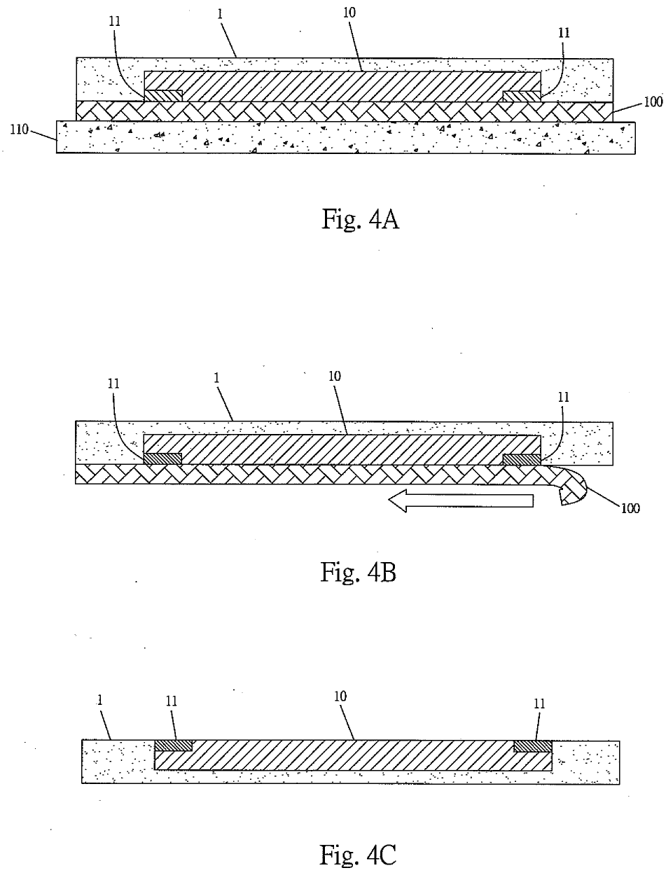

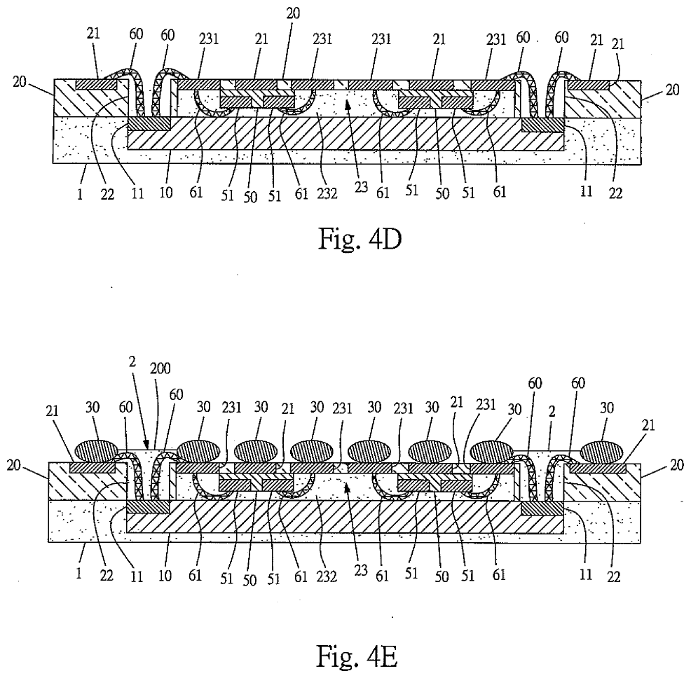

With reference to FIGS. 4A to 4E, and 12, the second embodiment of the present invention is illustrated. The steps of the second embodiment have identical steps as those in the first embodiment. The contents of step A shown in the FIG. 3A and step B shown in FIG. 3B to 3C are identical to those illustrated in the steps A and B of the above first embodiment, and therefore, the details will not be further described herein. However, in step C shown in FIG. 4D, a hollow area 23 is formed in a lower side of the substrate 20, and then an inner chip 50 (which are different from the chip 10 not located in the hollow area 23) is installed in the hollow area 23 of the substrate 20. A bottom side of the inner chip 50 has a plurality of joints 51 connected to a plurality of inner joints 231 (which are different from the joints 21 of the substrate 20) on an inner side of the hollow area 23 by a plurality of conductive wires 61. The inner joints 231 of the hollow area 23 pass through the substrate 20 to expose on an upper side of the substrate 20. A packaging material 232 seals the hollow area 23. The step D of the second embodiment is illustrated in FIG. 3E, the contents of step D are identical to those illustrated as in the step D of the first embodiment, and therefore, the details will not be further described herein.

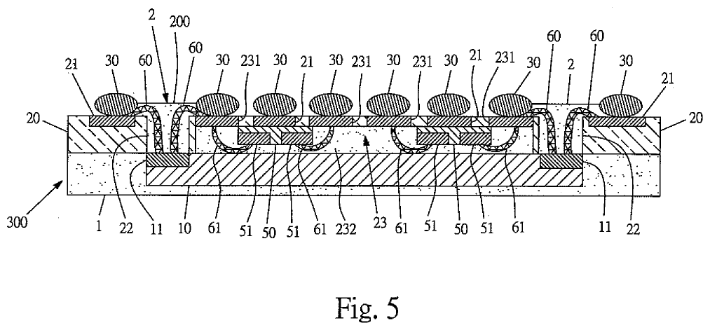

With reference to FIG. 5, by using above mentioned steps, the FOWBCSP ship with a package structure 300 of FIG. 3 can further be formed as a structure shown in FIG. 5. The structure and effects of the structure shown in FIG. 5 are identical to those of FIG. 3, and therefore, the details will not be further described herein. However, the structure of FIG. 5 further contains the following elements.

A hollow area 23 is formed in a lower side the substrate 20, and an inner chip 50 (which are different from the chip 10 not located in the hollow area 23) is installed in the hollow area 23 of the substrate 20. A bottom side of the inner chip 50 has a plurality of joints 51 connecting to a plurality of inner joints 231 (which are different from the joints 21 of the substrate 20) on an inner side of the hollow area 23 by a plurality of conductive wires 61. The inner joints 231 of the hollow area 23 pass through the substrate 20 to expose on an upper side of the substrate 20. A packaging material 232 seals the hollow area 23.

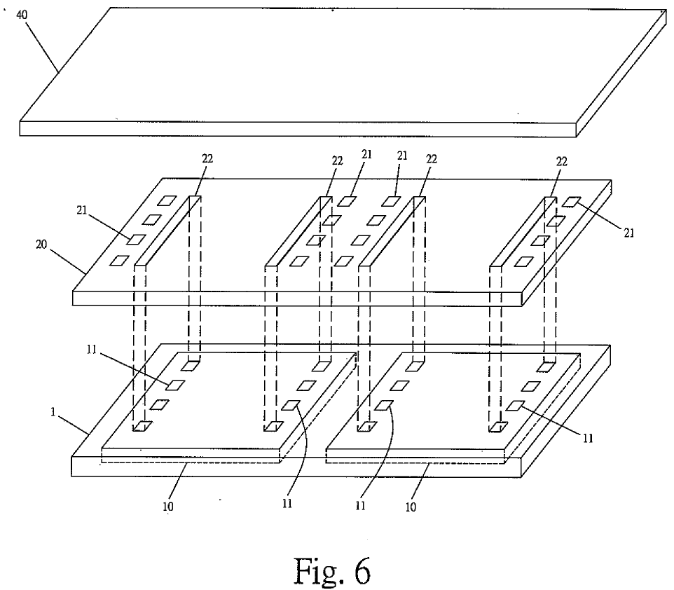

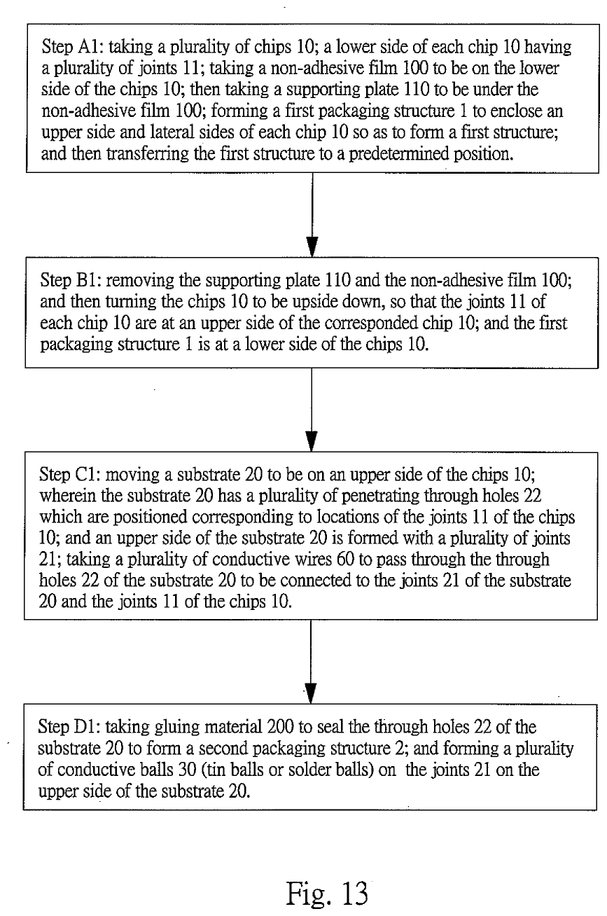

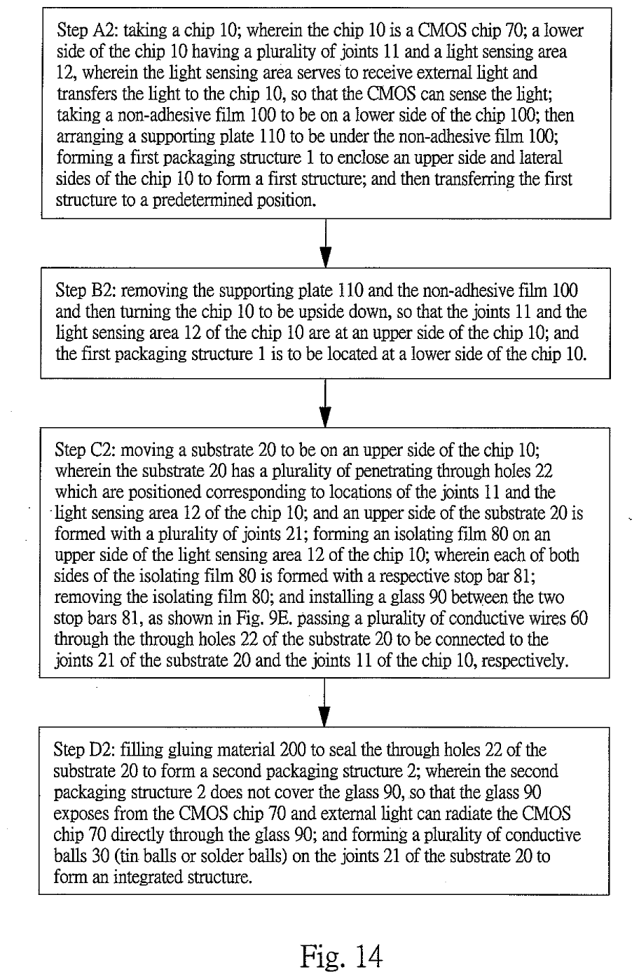

With reference to FIGS. 6 to 7E, and 13, the third embodiment of the present invention is illustrated. FIGS. 6 to 7E, and 13 illustrate a process in that a plurality of chips 10 are packaged by only one packaging structure. The process comprises the following steps of:

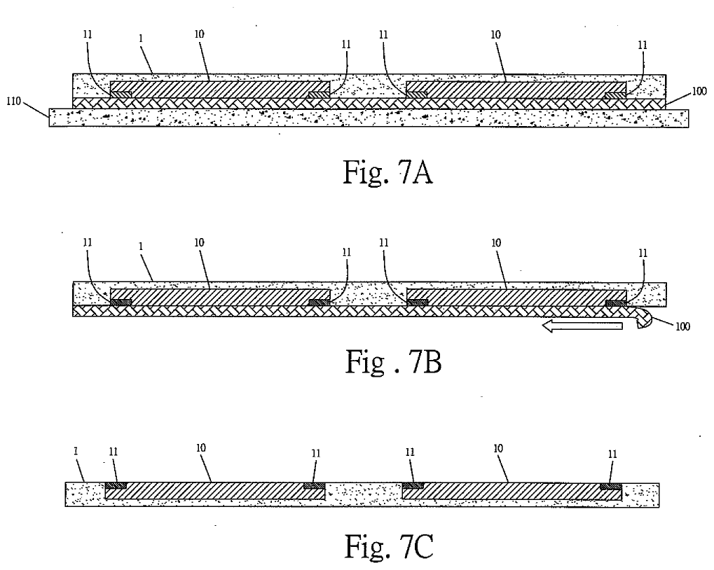

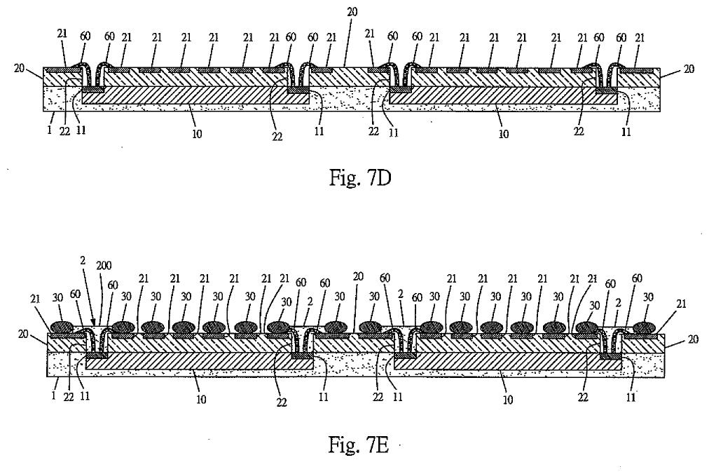

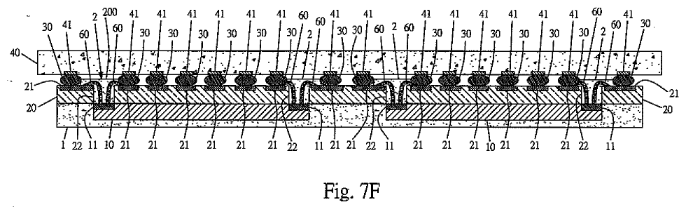

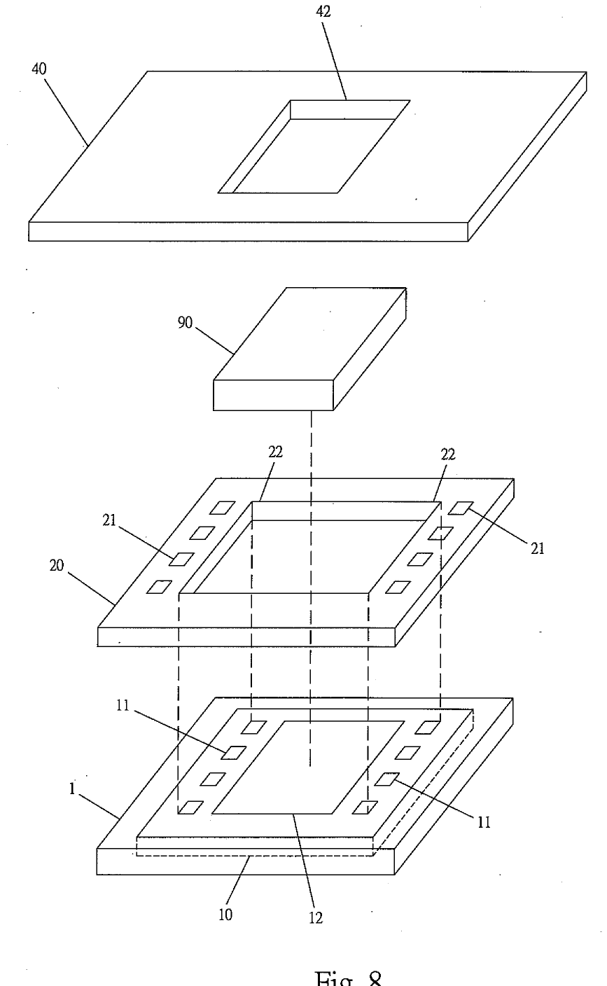

Step A1: as shown in FIG. 7A, taking a plurality of chips 10; a lower side of each chip 10 having a plurality of joints 11; taking a non-adhesive film 100 to be on the lower side of the chips 10; then taking a supporting plate 110 to be under the non-adhesive film 100; forming a first packaging structure 1 to enclose an upper side and lateral sides of each chip 10 so as to form a first structure; and then transferring the first structure to a predetermined position.

Step B1: with reference to FIG. 7B, removing the supporting plate 110 and the non-adhesive film 100; and then turning the chips 10 to be upside down, as shown in FIG. 7C so that the joints 11 of each chip 10 are at an upper side of the corresponded chip 10; and the first packaging structure 1 is at a lower side of the chips 10.

Step C1: referring to FIG. 7D, moving a substrate 20 to be on an upper side of the chips 10; wherein the substrate 20 has a plurality of penetrating through holes 22 which are positioned corresponding to locations of the joints 11 of the chips 10; and an upper side of the substrate 20 is formed with a plurality of joints 21; taking a plurality of conductive wires 60 to pass through the through holes 22 of the substrate 20 to be connected to the joints 21 of the substrate 20 and the joints 11 of the chips 10.

Step D1: as shown in FIG. 7E, taking gluing material 200 to seal the through holes 22 of the substrate 20 to form a second packaging structure 2; and forming a plurality of conductive balls 30 (tin balls or solder balls) on the joints 21 on the upper side of the substrate 20.

As shown in FIG. 7F, in application, above mentioned structure is cut into multiple units according to the location of each chip 10, so that each chip 10 and related substrate 20 form an integrated structure; and taking a circuit board 40 on the upper side of the substrate 20 of the integrated structure; wherein the circuit board 40 has a plurality of joints 41 connected to the conductive balls 30 on the joints 21 of the substrate 20 so as to form an electrical connection therebetween.

In the present invention, the chip 10 can be one of a variety of different kinds of chips, such as a MCU chip or a logical chip.

As shown in FIGS. 8 to 9G, and 14, the fourth embodiment of the present invention is illustrated. In this embodiment, the chip 10 in above embodiment is a COMS chip 70. The process of the fourth embodiment includes the following steps of:

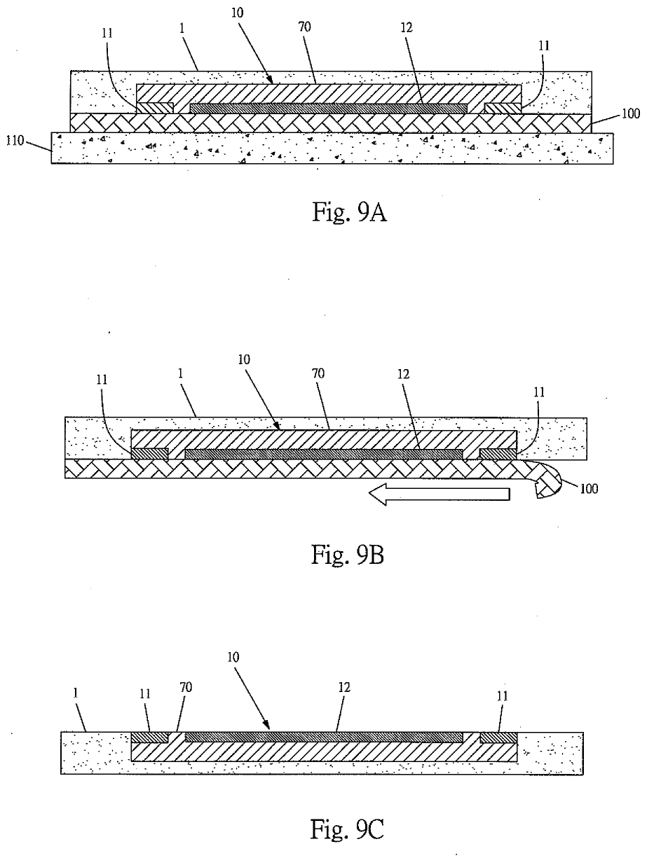

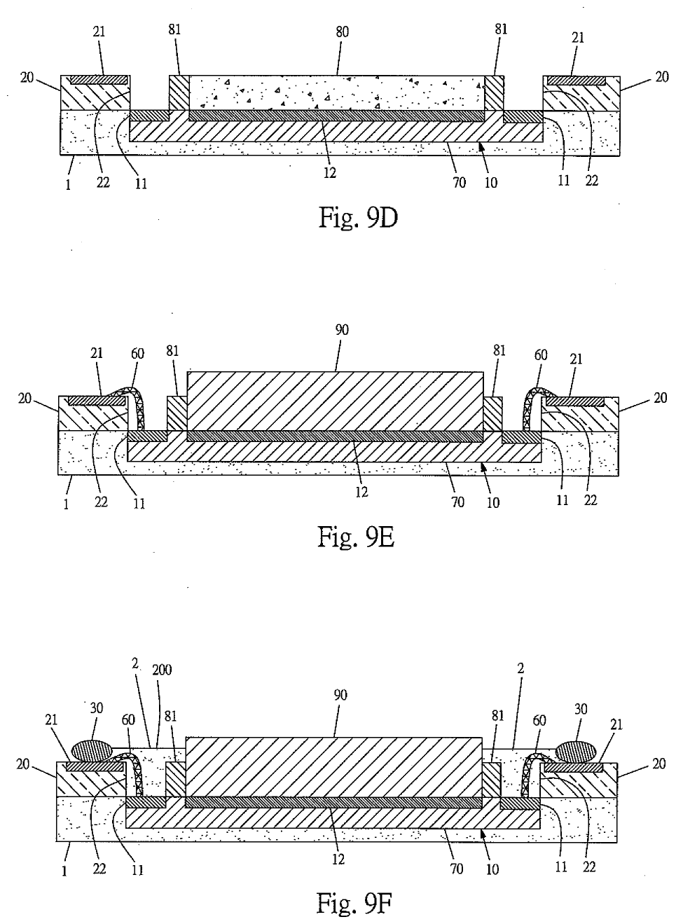

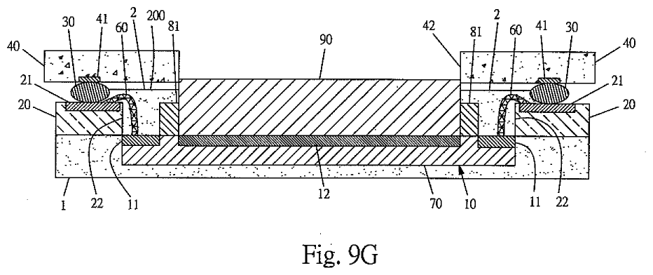

Step A2: as shown in FIG. 9A, taking a chip 10; wherein the chip 10 is a CMOS chip 70; a lower side of the chip 10 having a plurality of joints 11 and a light sensing area 12, wherein the light sensing area serves to receive external light and transfers the light to the chip 10, so that the CMOS can sense the light;

Taking a non-adhesive film 100 to be on a lower side of the chip 100; then arranging a supporting plate 110 to be under the non-adhesive film 100; forming a first packaging structure 1 to enclose an upper side and lateral sides of the chip 10 to form a first structure; and then transferring the first structure to a predetermined position.

Step B2: with reference to FIG. 9B, removing the supporting plate 110 and the non-adhesive film 100 and then turning the chip 10 to be upside down, as shown in FIG. 9C so that the joints 11 and the light sensing area 12 of the chip 10 are at an upper side of the chip 10; and the first packaging structure 1 is to be located at a lower side of the chip 10.

Step C2: referring to FIG. 9D, moving a substrate 20 to be on an upper side of the chip 10; wherein the substrate 20 has a plurality of penetrating through holes 22 which are positioned corresponding to locations of the joints 11 and the light sensing area 12 of the chip 10; and an upper side of the substrate 20 is formed with a plurality of joints 21;

Forming an isolating film 80 on an upper side of the light sensing area 12 of the chip 10; wherein each of both sides of the isolating film 80 is formed with a respective stop bar 81; removing the isolating film 80; and installing a glass 90 between the two stop bars 81, as shown in FIG. 9E; Passing a plurality of conductive wires 60 through the through holes 22 of the substrate 20 to be connected to the joints 21 of the substrate 20 and the joints 11 of the chip 10, respectively.

Step D2: as shown in FIG. 9F, filling gluing material 200 to seal the through holes 22 of the substrate 20 to form a second packaging structure 2; wherein the second packaging structure 2 does not cover the glass 90, so that the glass 90 exposes from the CMOS chip 70 and external light can radiate the CMOS chip 70 directly through the glass 90; and forming a plurality of conductive balls 30 (tin balls or solder balls) on the joints 21 of the substrate 20 to form an integrated structure.

As shown in FIG. 9G, in application, a circuit board 40 is arranged on the upper side of the substrate 20 of the integrated structure; wherein the circuit board 40 is a soft board. The circuit board 40 has a through hole 42 which is positioned corresponding to locations of the glass 90, so that external light can pass through the through hole 42 and the glass 90 to radiate the CMOS chip 70. The circuit board 40 has a plurality of joints 41 connected to the conductive balls 30 on the joints 21 of the substrate 20 so as to form an electrical connection therebetween.

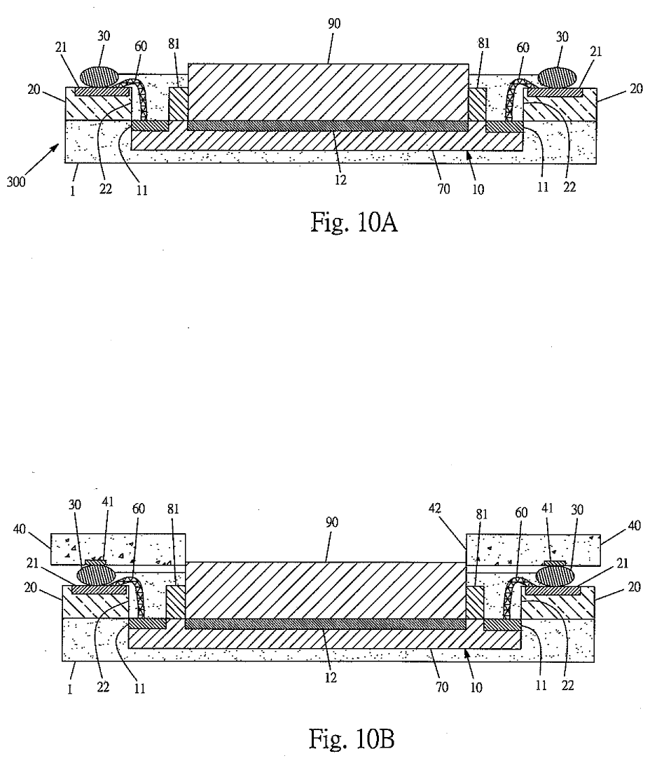

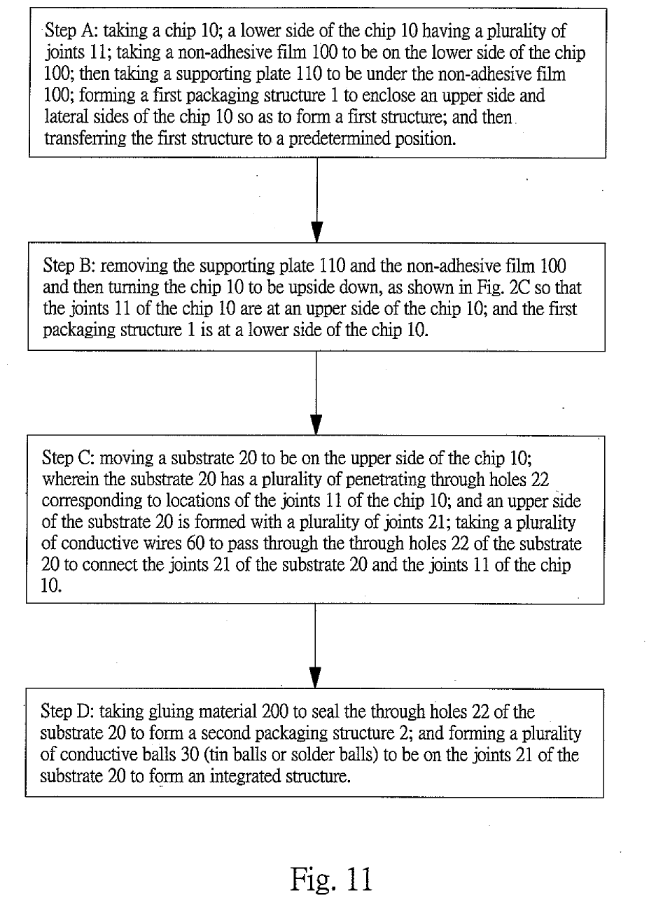

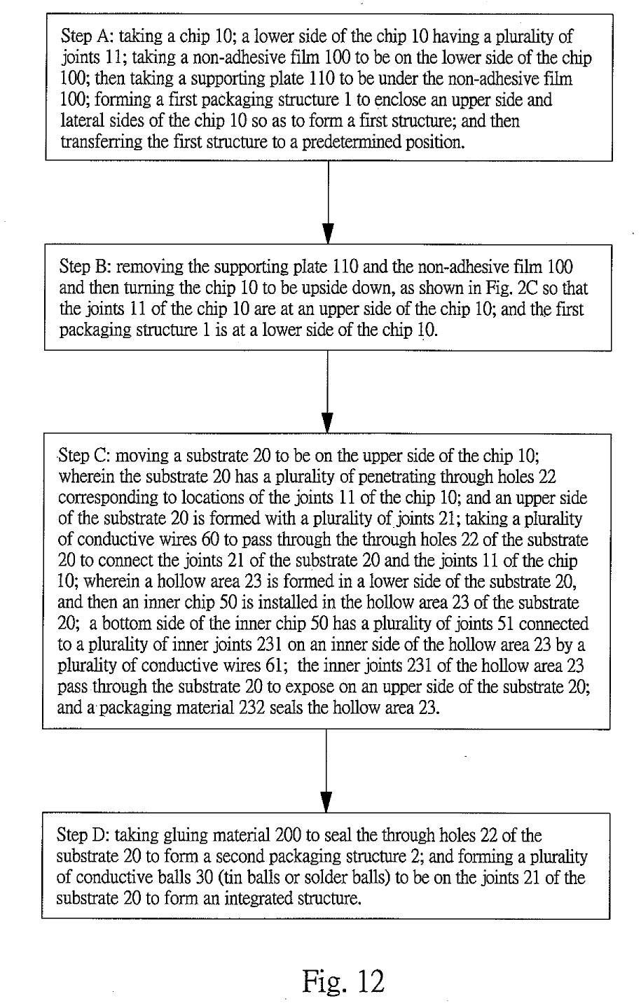

With reference to FIG. 10A, above mentioned structure can be formed as a FOWBCSP (Fan out wafer bonding chip scale package) chip module with a packaging structure 300 enclosing thereon. The structure contains the following elements.

A CMOS chip 70 has a plurality of joints 11 and a light sensing area 12 on an upper side thereof.

A first packaging structure 1 is formed on a lower side and lateral sides of the CMOS chip 70.

A substrate 20 is installed on the upper side of the CMOS chip 70. The substrate 20 has a plurality of penetrating through holes 22 which are located corresponding to locations of the joints 11 and the light sensing area 12 of the CMOS chip 70; and an upper side of the substrate 20 is formed with a plurality of joints 21. A plurality of conductive wires 60 pass through the through holes 22 of the substrate 20 to be connected to the joints 21 of the substrate 20 and the joints 11 of the CMOS chip 70.

Two stop bars 81 are formed on outer ends of an upper side of the light sensing area 12 of the CMOS chip 70.

A glass 90 is installed between the two stop bars 81.

Each of the through holes 22 of the substrate 20 is sealed by gluing material 200 to form a second packaging structure 2. The second packaging structure 2 does not cover the glass 90, so that the glass 90 exposes out and external light can radiate the CMOS chip 70 directly through the glass 90.

The joints 21 on the upper side of the substrate 20 have a plurality of conductive balls 30 (tin balls or solder balls).

With reference to FIG. 10B, in application, a circuit board 40 is arranged on the upper side of the substrate 20. The circuit board 40 has a plurality of joints 41 to be connected to the conductive balls 30 on the joints 21 of the substrate 20 so as to form an electrical connection therebetween.

Similarly, a plurality of CMOS chips 70 can be arranged to be packaged by only one packaging structure. The process to package the CMOS chips 70 is identical to those of the above third embodiment, and therefore, the details will not be further described herein.

Advantages of the present invention are that only a few of through holes are formed on the substrate, so that a plurality of conductive wires can pass through of the through holes in the same time. As a result, the substrate does not need to have a large number of through holes as those used prior art, so that the time and cost of the process are reduced. Moreover, in the present invention, only a few of areas with exposed conductive wires need to be packaged. The packaging area does not need to cover the whole upper side of the chip and the substrate as that of the prior art. Therefore, the packaging process in the present invention saves the cost and time in manufacturing. In the present invention, the conductive wires have short length, and most parts of the conductive wires are hidden within the through holes. As a result, the conductive wires do not expose obviously and many dangerous issues are avoided.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A FOWBCSP chip module with a packaging structure, wherein, the FOWBCSP is Fan out wafer bonding chip scale package, comprising:
a chip having joints on an upper side thereof;
a first packing structure enclosing a lower side and lateral sides of the chip;
a substrate at the upper side of the chip; the substrate being formed with a plurality of penetrating through holes at positions corresponding to the joints of the chip; and an upper side of the substrate being formed with a plurality of joints; and conductive wires passing through the through holes of the substrate to connect the joints of the substrate and the joints of the chip; and
wherein each of the through holes of the substrate is formed with a respective second packaging structure by filling gluing material to seal the through hole of the substrate and each of the joints on the upper side of the substrate is formed with a conductive ball, respectively; and
wherein an interior of the substrate (20) is formed with a hollow area (23) and an inner chip is installed within the hollow area (23): a bottom side of the inner chip (50) has a plurality of joints (51) connecting to a plurality of inner joints (231) on an inner side of the hollow area (23) by a plurality of conductive wires (61), respectively; the inner joints (231) of the hollow area (23) pass through the substrates (20) to expose on the upper side of the substrate (20); and some of the inner joints (231) are identical to the joints (21) of the substrate (20); and a packaging material (232) seals the hollow area (23).

2-3. (canceled)

4. The FOWBCSP chip module with a packaging structure as claimed in claim 1, wherein the conductive balls are tin balls or solder balls.

5. The FOWBCSP chip module with a packaging structure as claimed in claim 1, wherein the chip is a logical chip.

6. The FOWBCSP chip module with a packaging structure as claimed in claim 1, further comprising:
a circuit board arranged on the upper side of the substrate, the circuit board having a plurality of joints to be connected to the conductive balls on the joints on the upper side of the substrate so as to form an electrical connection therebetween.

7-12. (canceled)
